(19) United States
(12) Patent Application Publication
(10) Pub. No.: US 2021/0361085 A1
(43) Pub. Date: Nov. 25, 2021

(54) A NEW HINGE DESIGN ON ANTIGUA LIKE DEVICE

(71) Applicants: Yunfei ZHU, Shanghai (CN); Hewlett-Packard Development Company, L.P., Spring, TX (US)

(72) Inventor: Yun Fei Zhu, Shanghai (CN)

(73) Assignee: Hewlett-Packard Development Company, L.P., Spring, TX (US)

(21) Appl. No.: 17/045,508

(22) PCT Filed: Sep. 14, 2018
(86) PCT No.: PCT/CN2018/105672

§ 371 Date: Oct. 6, 2020

(51) Int. Cl. A47F 10/02; F16C 11/10; H05K 5/02

(52) U.S. Cl. CPC A47F 10/02; H05K 5/0234; F16C 11/10

(57) ABSTRACT

A display tilting apparatus (300) may include a spindle (310), a middle bearing (312) mounted on the spindle (310) and coupled to a moving bracket (304), a pair of damping thrust bearings (314) mounted on the spindle (310) and coupled to a fixed bracket (306), and a ratchet-pawl assembly (316) mounted on the spindle (310) and coupled to the moving bracket (304). The ratchet-pawl assembly (316) may cause the spindle (310) and the middle bearing (312) to rotate with the moving bracket (304) during pivoting of the moving bracket (304) to a first direction (320) such that the pair of damping thrust bearings (314) may provide a first frictional force to the moving bracket (304) in the first direction (320). Further, the middle bearing (312) may provide a second frictional force to the moving bracket (304) during pivoting of the moving bracket (304) to a second direction (322) that is opposite to the first direction (320).

### BACKGROUND

In retail industry, a number of point-of-sale (POS) terminals may be used throughout a retail store. The POS terminals having a display monitor may be used in commercial areas, such as department stores and the restaurants, as an information-display apparatus. The POS terminals may be used to display product information to retail customers or may be used as an interactive retail terminal which assists the customers in response to a customer's input. In such scenarios, a display tilting apparatus may be used to adjust an angle of a moving bracket, on which the display monitor is mounted, to a desirable position.

### BRIEF DESCRIPTION OF THE DRAWINGS

Examples are described in the following detailed description and in reference to the drawings, in which:

FIG. 1A is a perspective view of an example display tilting apparatus to rotate a moving bracket relative to a fixed bracket;

FIG. 1B is a perspective view of the example display tilting apparatus of FIG. 1A, depicting additional features;

FIG. 2A is an exploded view of an example display tilting apparatus;

FIG. 2B is an exploded view of the example display tilting apparatus of FIG. 2A, depicting additional features;

FIG. 3A is a perspective view of an example display apparatus, depicting a lock position of a ratchet-pawl assembly during rotation of a moving bracket in a first direction;

FIG. 3B is a perspective view of the example display apparatus of FIG. 3A, depicting an unlock position of the ratchet-pawl assembly during rotation of the moving bracket in a second direction; and

FIGS. 4A and 4B are schematic diagrams of the example display apparatus of FIG. 3A, depicting a display monitor in a second rotational position and a first rotational position, respectively.

### DETAILED DESCRIPTION

The point-of-sale (POS) terminals having a display monitor may be used in commercial areas such as department stores and the restaurants as an information-display apparatus. The POS terminals may be used to display product information to retail customers or may be used as an interactive retail terminal to assist the customers. During operation of the display monitor, an operator may adjust the angle of the display monitor to a desirable position on a customer's side or rotate the display monitor back to an operator's side. In such scenarios, a display tilting apparatus may be used to rotate the display monitor to the desirable position. To enhance a user experience, the display monitor may have to be rotated to the customer's side and the operator's side with a different torque or frictional force and the display monitor can be locked at multiple different orientations or angles.

Examples described herein may provide a display tilting apparatus for an electronic device. The display tilting apparatus may include a middle bearing mounted on a spindle and coupled to a moving bracket, a pair of damping thrust bearings mounted on the spindle and coupled to a fixed bracket, and a ratchet-pawl assembly mounted on the spindle and coupled to the moving bracket. The ratchet-pawl assembly may be in a lock position and the pair of damping thrust bearings may provide a first frictional force during rotation of the moving bracket in a first direction. Further, the ratchet-pawl assembly may be in an unlock position and the middle bearing may provide a second frictional force during rotation of the moving bracket in a second direction.

Examples described herein may utilize the ratchet-pawl assembly along with the middle bearing and the pair of damping thrust bearings to enhance the life of the display tilting apparatus. Examples described herein may provide the first frictional force during pivoting of the moving bracket to the first direction and provide the second frictional force during pivoting of the moving bracket to the second direction, where the first frictional force is greater than the second frictional force.

In the following description, for purposes of explanation, numerous specific details are set forth in order to provide a thorough understanding of the present techniques. It will be apparent, however, to one skilled in the art that the present apparatus, devices and systems may be practiced without these specific details. Reference in the specification to “an example” or similar language means that a particular feature, structure, or characteristic described is included in at least that one example, but not necessarily in other examples.

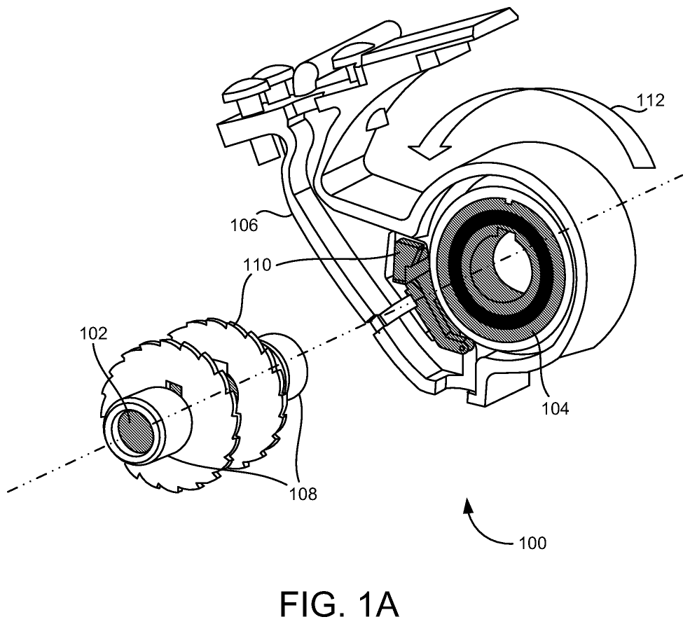

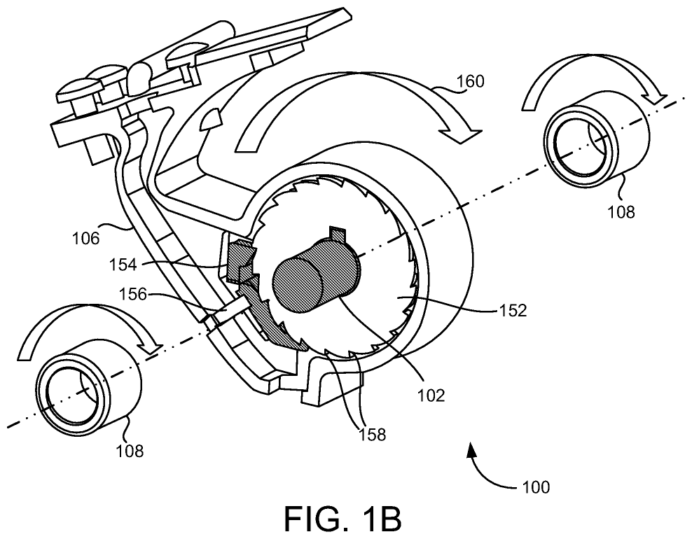

FIG. 1A is a perspective view of an example display tilting apparatus 100 to rotate a moving bracket 106 relative to a fixed bracket. Display tilting apparatus 100 may be used to rotate a display monitor between a customer's side and an operator's side about a pivot axis, for instance, in a retail environment. Example display tilting apparatus 100 may include a spindle 102. Further, display tilting apparatus 100 may include a middle bearing 104 mounted on spindle 102 and coupled to moving bracket 106. Example middle bearing 104 may be a two-way bearing with same damping in both directions.

Furthermore, display tilting apparatus 100 may include a pair of damping thrust bearings 108 mounted on spindle 102. The pair of damping thrust bearings 108 can be coupled to the fixed bracket. In one example, each damping thrust bearing 108 may be a one-way bearing. Also, display tilting apparatus 100 may include a ratchet-pawl assembly 110 mounted on spindle 102 and coupled to moving bracket 106. Display tilting apparatus 100 may be arranged to rotate moving bracket 106 relative to the fixed bracket using middle bearing 104, pair of damping thrust bearings 108, and ratchet-pawl assembly 110.

During pivoting of moving bracket 106 to a first direction (e.g., as shown by arrow 160 of FIG. 1B), ratchet-pawl assembly 110 may cause spindle 102 and middle bearing 104 to rotate with moving bracket 106. In this example, middle bearing 104 may lose the function of bearing and pair of damping thrust bearings 108 may provide a first frictional force to moving bracket 106 in the first direction (e.g., as shown in FIG. 1B). During pivoting of moving bracket 106 to a second direction (e.g., as shown by arrow 112 of FIG. 1A) that is opposite to the first direction, middle bearing 104 may provide a second frictional force to moving bracket 106 (e.g., as shown in FIG. 1A). In the example shown in FIG. 1A, spindle 102, ratchet gears of ratchet-pawl assembly 110, and pair of damping thrust bearings 108 may not move along with moving bracket 106 in the second direction.

FIG. 1B is a perspective view of example display tilting apparatus 100 of FIG. 1A, depicting additional features. For example, similarly named elements of FIG. 1B may be similar in structure and/or function to elements described with respect to FIG. 1A. In one example, ratchet-pawl assembly 110 may include a pair of ratchet gears 152 mounted on spindle 102 at opposite sides of middle bearing 104 (e.g., as shown in FIG. 1A). In one example, pair of damp thrust bearings 108 may be mounted on opposite ends of spindle 102. Further, ratchet-pawl assembly 110 may include a locking pawl 154 connected to moving bracket 106 and unidirectionally engages with pair of ratchet gears 152. Furthermore, ratchet-pawl assembly 110 may include an elastic member 156 connected between moving bracket 106 and locking pawl 154 to cause locking pawl 154 to engage with pair of ratchet gears 152. Example elastic member 156 may be a detent or a spring.

In one example, spindle 102 may unrotatably support middle bearing 104 (e.g., as shown in FIG. 1A), pair of ratchet gears 152, and pair of damping thrust bearings 108. In this example, spindle 102 may include a shape (e.g., a flat surface or a protruding feature) and is fitted into a similarly shaped through-hole in middle bearing 104 and ratchet gears 152. Similarly, spindle 102 may unrotatably support damping thrust bearings 108.

Each ratchet gear 152 may include a plurality of notches 158 in an outer circumference. In one example, elastic member 156 may lock locking pawl 154 against pair of ratchet gears 152 during rotation of moving bracket 106 in the first direction (e.g., as shown by arrow 160 of FIG. 1B). In this example, pair of ratchet gears 152 may rotate along with moving bracket 106, which in turn rotate spindle 102 and middle bearing 104, thereby causing middle bearing 104 to lose the bearing function. In this case, pair of damping thrust bearings 108 may provide the first frictional force to moving bracket 106 in the first direction. Further, ratchet-pawl assembly 110 may control pivoting of moving bracket 106 to the first direction. In this example, locking pawl 154 may engage with ratchet gears 152 to hold the display monitor at multiple different positions during rotation of moving bracket 106 in the first direction.

In another example, elastic member 156 may cause locking pawl 154 to engage with a following notch of pair of ratchet gears 152 during rotation of moving bracket 106 in the second direction (e.g., as shown by arrow 112 of FIG. 1A). In this example, locking pawl may slide on the outer circumference such that ratchet-pawl assembly 110 (e.g., pair of ratchet gears 152), spindle 102, and pair of damping thrust bearings 108 do not move or rotate along with moving bracket 106 in the second direction. In this case, middle bearing 104 may provide a second frictional force to moving bracket 106.

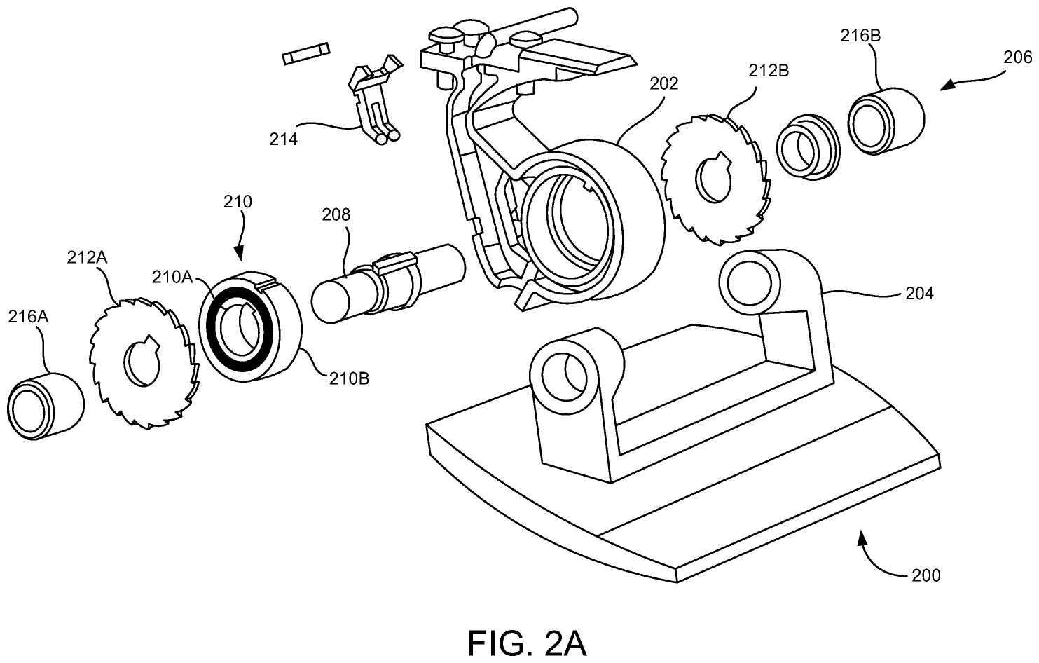

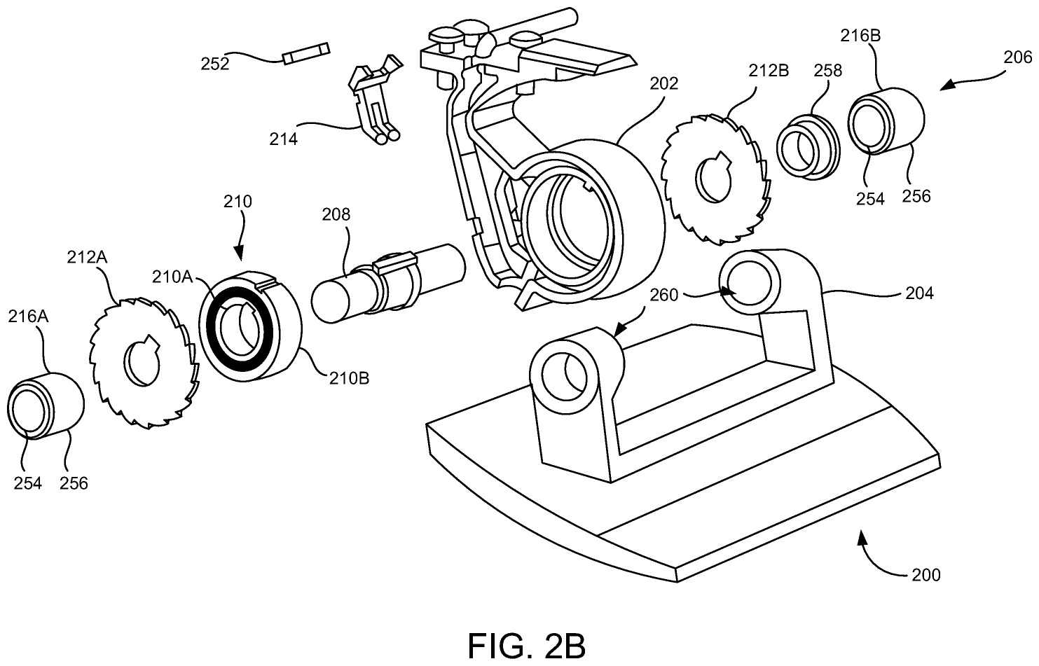

FIG. 2A is an exploded view of an example display tilting apparatus 200. Example display tilting apparatus 200 may include a moving bracket 202 to support a display monitor. Further, display tilting apparatus 200 may include a fixed bracket 204. Furthermore, display tilting apparatus 200 may include a tilt mechanism 206 to pivotally connect moving bracket 202 to fixed bracket 204 via a pivot axis. Example tilt mechanism 206 may include a spindle 208. Further, tilt mechanism 206 may include a middle bearing 210 having an inner ring 210A to fixedly mount on spindle 208 and an outer ring 210B. In this example, moving bracket 202 may fixedly mount on outer ring 210B. Middle bearing 210 may provide a bearing torque via rotation of one ring while the other ring is stationary.

Furthermore, tilt mechanism 206 may include a pair of ratchet gears 212A and 212B to fixedly mount on spindle 208. In one example, ratchet gears 212A and 212B may be disposed at opposite sides of middle bearing 210. Also, tilt mechanism 206 may include a locking pawl 214 to fixedly connect to moving bracket 202 and unidirectionally engage with ratchet gears 212A and 212B. Even though tilt mechanism 206 is described with pair of ratchet gears 212A and 212B, tilt mechanism 206 can also be implemented with a single ratchet gear.

Further, tilt mechanism 206 may include a pair of damping thrust bearings 216A and 216B to fixedly mount on spindle 208 at opposite ends and to couple to fixed bracket 204. In one example, damping thrust bearings 216A and 216B may provide a first frictional force to moving bracket 202 during pivoting of moving bracket 202 from a first rotational position to a second rotational position. In this example, spindle 208, middle bearing 210 including inner ring 210A and outer ring 210B, and ratchet gears 212A and 212B may rotate together during pivoting of moving bracket 202 from the first rotational position to the second rotational position.

Further, middle bearing 210 may provide a second frictional force to moving bracket 202 during pivoting of moving bracket 202 from the second rotational position to the first rotational position. In this example, spindle 208, inner ring 210A, ratchet gears 212A and 212B, and pair of damping thrust bearings 216A and 216B may not move along with moving bracket 202. The second frictional force is provided by middle bearing 210, for instance, via relative movement of outer ring 210B with respect to inner ring 210A of middle bearing 210. In this example, pivoting of moving bracket 202 with respect to fixed bracket 204 may be inhibited by the second frictional force between inner ring 210A and outer ring 210B.

FIG. 2B is an exploded view of example display tilting apparatus 200 of FIG. 2A, depicting additional features. Similarly named elements of FIG. 2B may be similar in structure and/or function to elements described with respect to FIG. 2A. As shown in FIG. 2B, tilt mechanism 206 may include an elastic member 252 that can be connected between moving bracket 202 and locking pawl 214 to cause locking pawl 214 to engage with ratchet gears 212A and 212B.

Further, each of damping thrust bearings 216A and 216B may include an inner ring 254 mounted on spindle 208 and an outer ring 256. Each of damping thrust bearings 216A and 216B may provide a bearing torque via rotation of one ring while the other ring is stationary. In this example, fixed bracket 204 may be mounted on outer ring 256. Inner ring 254 may move relative to outer ring 256 to provide the first frictional force to moving bracket 202 during pivoting of moving bracket 202 from the first rotational position to the second rotational position. In this example, pivoting of moving bracket 202 with respect to fixed bracket 204 may be inhibited by the first frictional force between inner ring 254 and outer ring 256.

In some examples, tilt mechanism 206 may include any other component such as a bushing 258 mounted on spindle 208. Bushing 258 may be disposed between a ratchet gear (e.g., ratchet gear 212B) and a damping thrust bearing (e.g., damping thrust bearing 216B). In other examples, a pair of bushings may be disposed between ratchet gears 212A and 212B and damping thrust bearings 216A and 216B. In other examples, the component may be a stopper to regulate the pivoting movement of moving bracket 202.

As shown in FIGS. 2A and 2B, spindle 208 may unrotatably support inner ring 210A of middle bearing 210, ratchet gears 212A and 212B, and damping thrust bearings 216A and 216B. In this example, spindle 208 may include at least one flat surface or protruding surface and is inserted into similarly shaped openings of inner ring 210A of middle bearing 210 and ratchet gears 212A and 212B. Similarly, spindle 208 may unrotatably support damping thrust bearings 216A and 216B.

Moving bracket 202 may be unrotatably mounted on outer ring 210B of middle bearing 210. In this example, outer ring 210B may include a recess portion and is inserted into a similarly shaped opening of moving bracket 202. Similarly, opposite ends of fixed bracket 204 may be unrotatably mounted on respective outer rings 256 of damping thrust bearings 216A and 216B, for instance, via openings 260.

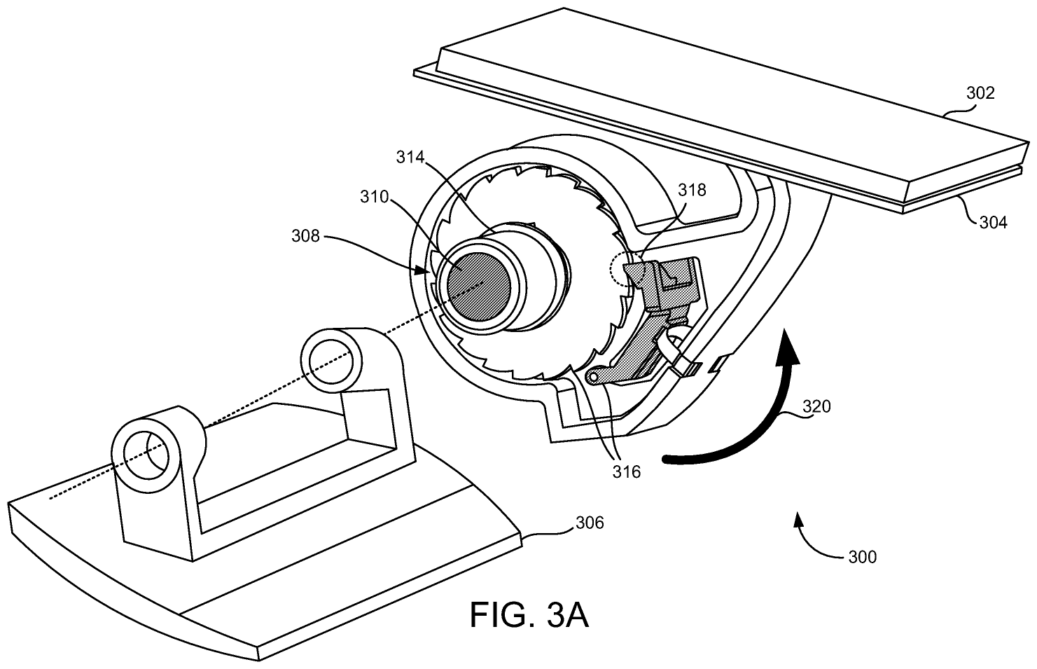

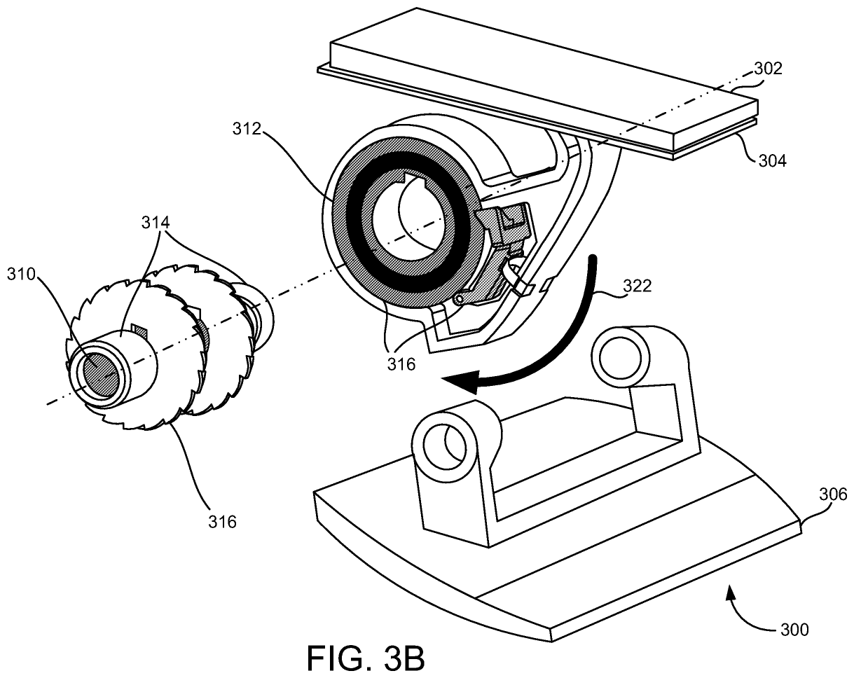

FIG. 3A is a perspective view of an example display apparatus 300, depicting a lock position 318 of a ratchet-pawl assembly 316 during rotation of a moving bracket 304 in a first direction (e.g., as shown by arrow 320). FIG. 3B is a perspective view of example display apparatus 300 of FIG. 3A, depicting an unlock position of ratchet-pawl assembly 316 during rotation of moving bracket 304 in a second direction (e.g., as shown by arrow 322). The second direction may be opposite to the first direction. Similarly named elements of FIG. 3A may be similar in structure and/or function to elements described below with respect to FIG. 3B.

Display apparatus 300 may include a display monitor 302 and a moving bracket 304 to support display monitor 302. Example display monitor 302 may include a touch screen display. Example display monitor 302 may include liquid crystal display (LCD), light emitting diode (LED), electro-luminescent (EL) display, or the like. For example, display monitor 302 may be fitted to moving bracket 304, for instance, using fasteners such as screws.

Further, display apparatus 300 may include a fixed bracket 306 pivotably connected to moving bracket 304. Furthermore, display apparatus 300 may include a display tilting apparatus 308 to rotatably support display monitor 302. Display tilting apparatus 308 may include a spindle 310. Display tilting apparatus 308 may include a middle bearing 312 (e.g., as shown in FIG. 3B) mounted on spindle 310 and coupled to moving bracket 304.

Display tilting apparatus 308 may include a pair of damping thrust bearings 314 mounted on spindle 310 and coupled to fixed bracket 306. Display tilting apparatus 308 may include a ratchet-pawl assembly 316 mounted on spindle 310 and connected to moving bracket 304. In the example shown in FIG. 3A, ratchet-pawl assembly 316 may be in a lock position (e.g., as shown by 318 of FIG. 3A) and pair of damping thrust bearings 314 may provide a first frictional force during rotation of moving bracket 304 in the first direction (e.g., as shown by arrow 320).

In one example, spindle 310, middle bearing 312, ratchet-pawl assembly 316, and pair of damping thrust bearings 314 may rotate along with moving bracket 304 in the first direction such that pair of damping thrust bearings 314 provide the first frictional force when ratchet-pawl assembly 316 is in the lock position. In this example, ratchet-pawl assembly 316 may control pivoting of moving bracket 304 in the first direction and adjusts the angle of display monitor 302 to be any desirable angle.

Further, ratchet-pawl assembly 316 may be in an unlock position and middle bearing 312 may provide a second frictional force during rotation of moving bracket 304 in a second direction (e.g., as shown by arrow 322). In one example, middle bearing 312 may rotate along with moving bracket 304 in the second direction such that middle bearing 312 provides the second frictional force when ratchet-pawl assembly 316 is in the unlock position.

Even though the display tilting apparatuses in FIGS. 1-3 may be described using a pair of ratchet gears and a pair of damping thrust bearings, the display tilting apparatuses can also be implemented with any number of ratchet gears and damping thrust bearings such that the damping thrust bearings may provide a first frictional resistance in one direction, while at least one other bearing may provide a second frictional resistance in an opposite direction. Further, FIGS. 2A, 2B, 3A, and 3B may depict an example structure for fixed brackets 204 and 306, however, any other structure can also be implemented for the fixed bracket such that the fixed bracket may act as a stationary base and unrotatably coupled to the damping thrust bearings.

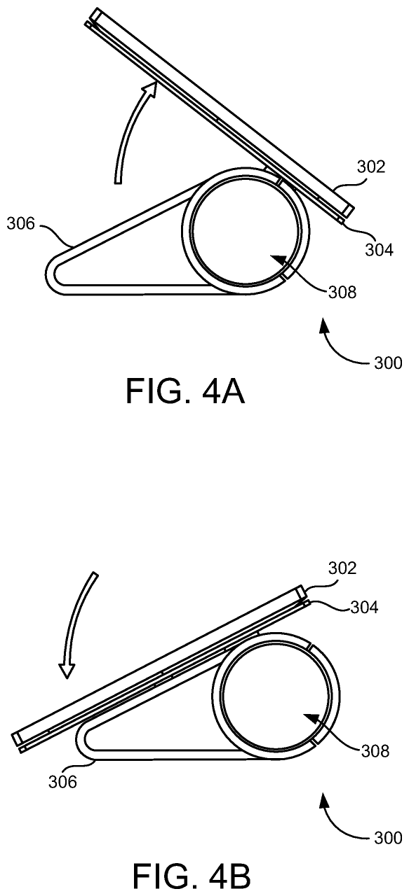

FIGS. 4A and 4B are schematic diagrams of example display apparatus 300 of FIG. 3A, depicting a display monitor 302 in a second rotational position and a first rotational position, respectively. For example, similarly named elements of FIGS. 4A and 4B may be similar in structure and/or function to elements described with respect to FIGS. 3A. When an operator tilts display monitor 302 towards a customer's side, i.e., a state of display monitor 302 may be changed to the second rotational position as shown in FIG. 4A, moving bracket 304 fitted to display monitor 302 may pivot with display monitor 302. In this example, display tilting apparatus 308 may provide the first frictional force to pivot display monitor 302 from the first rotational position to the second rotational position. For example, the first rotational position may correspond to an operator's side and the second rotational position may correspond to the customer's side.

As shown in FIG. 4B, display monitor 302 may be rotated back to the first rotational position. When the operator tilts display monitor 302 towards the operator's side, i.e., a state of display monitor 302 may be changed to the first rotational position as shown in FIG. 4B, moving bracket 304 fitted to display monitor 302 may pivot with display monitor 302. In this example, display tilting apparatus 308 may provide the second frictional force to pivot display monitor 302 from the second rotational position to the first rotational position. In one example, the second frictional force may be different (e.g., less than) from the first frictional force.

Thus, display monitor 302 can be rotated to the customer's side and the operator's side with different torque or frictional force and display monitor 302 can be locked at multiple different orientations or angles relative to fixed bracket 306 to enhance the user experience. Display tilting apparatus 308 described herein may be useful in adjusting the angle of display monitor 302, and particularly, suitable for adjusting the angle of display monitor 302 of an information-display apparatus, such as the POS terminal. Display tilting apparatus 308 may facilitate the use of display monitor 302 by various users, each of which may prefer display monitor 302 to be positioned at a different angle relative to fixed bracket 306.

Although the display tilting apparatus is applied to the display monitor of the POS terminal in the examples described in FIGS. 1-4, the display tilting apparatus described herein can also be implemented in other areas such as the panels (e.g., for customers) of the commutation-ticket vending machine, the automatic teller machine (ATM) of the bank, and the like. Examples described herein may adjust the angle of the display monitor between the operator's side and the customer's side to any desirable angle stepwise and prevent the display screen to tilt to the operator's side or customer's side unexpectedly and undisturbedly, thus improving the operability and stability of the display monitor.

It may be noted that the above-described examples of the present solution are for the purpose of illustration only. Although the solution has been described in conjunction with a specific embodiment thereof, numerous modifications may be possible without materially departing from the teachings and advantages of the subject matter described herein. Other substitutions, modifications and changes may be made without departing from the spirit of the present solution. All of the features disclosed in this specification (including any accompanying claims, abstract and drawings), and/or all of the steps of any method or process so disclosed, may be combined in any combination, except combinations where at least some of such features and/or steps are mutually exclusive.

The terms “include,” “have,” and variations thereof, as used herein, have the same meaning as the term “comprise” or appropriate variation thereof. Furthermore, the term “based on,” as used herein, means “based at least in part on.” Thus, a feature that is described as based on some stimulus can be based on the stimulus or a combination of stimuli including the stimulus.

The present description has been shown and described with reference to the foregoing examples. It is understood, however, that other forms, details, and examples can be made without departing from the spirit and scope of the present subject matter that is defined in the following claims.

What is claimed is:

1. A display tilting apparatus comprising:
a spindle;
a middle bearing mounted on the spindle and coupled to a moving bracket;
a pair of damping thrust bearings mounted on the spindle and coupled to a fixed bracket; and
a ratchet-pawl assembly mounted on the spindle and coupled to the moving bracket, wherein the ratchet-pawl assembly is to cause the spindle and the middle bearing to rotate with the moving bracket during pivoting of the moving bracket to a first direction, wherein the pair of damping thrust bearings are to provide a first frictional force to the moving bracket in the first direction, and wherein the middle bearing is to provide a second frictional force to the moving bracket during pivoting of the moving bracket to a second direction that is opposite to the first direction.

2. The display tilting apparatus of claim 1, wherein the ratchet-pawl assembly comprises:
a pair of ratchet gears mounted on the spindle at opposite sides of the middle bearing;
a locking pawl connected to the moving bracket and unidirectionally engages with the pair of ratchet gears; and
an elastic member connected between the moving bracket and the locking pawl to cause the locking pawl to engage with the pair of ratchet gears.

3. The display tilting apparatus of claim 2, wherein each ratchet gear has a plurality of notches in an outer circumference, wherein the elastic member is to cause the locking pawl to engage with a following notch of the pair of ratchet gears during rotation of the moving bracket in the second direction, and wherein the elastic member is to lock the locking pawl against the pair of ratchet gears during rotation of the moving bracket in the first direction.

4. The display tilting apparatus of claim 2, wherein the spindle unrotatably supports the middle bearing, the pair of ratchet gears, and the pair of damping thrust bearings, and wherein the pair of damp thrust bearings are mounted on opposite ends of the spindle.

5. The display tilting apparatus of claim 1, wherein each of the pair of damping thrust bearings is a one-way bearing, and wherein the middle bearing is a two-way bearing.

6. A display tilting apparatus comprising:
a moving bracket to support a display monitor;
a fixed bracket; and
a tilt mechanism to pivotally connect the moving bracket to the fixed bracket via a pivot axis, wherein the tilt mechanism comprises:
a spindle;
a middle bearing comprising:
an inner ring fixedly mounted on the spindle; and
an outer ring, wherein the moving bracket is fixedly mounted on the outer ring;
a pair of ratchet gears fixedly mounted on the spindle at opposite sides of the middle bearing;
a locking pawl fixedly connected to the moving bracket and unidirectionally engages with the pair of ratchet gears; and
a pair of damping thrust bearings fixedly mounted on the spindle at opposite ends and coupled to the fixed bracket.

7. The display tilting apparatus of claim 6, wherein the pair of damping thrust bearings are to provide a first frictional force to the moving bracket during pivoting of the moving bracket from a first rotational position to a second rotational position.

8. The display tilting apparatus of claim 6, wherein the middle bearing is to provide a second frictional force to the moving bracket during pivoting of the moving bracket from a second rotational position to a first rotational position.

9. The display tilting apparatus of claim 6, wherein the spindle, the middle bearing including the inner ring and the outer ring, and the pair of ratchet gears rotate together during pivoting of the moving bracket from a first rotational position to a second rotational position.

10. The display tilting apparatus of claim 6, wherein each of the pair of damping thrust bearings comprises:
an inner ring mounted on the spindle; and
an outer ring, wherein the fixed bracket is mounted on the outer ring.

11. The display tilting apparatus of claim 6, further comprising:
a bushing mounted on the spindle and disposed between a ratchet gear of the pair of ratchet gears and a damping thrust bearing of the pair of damping thrust bearings.

12. The display tilting apparatus of claim 6, wherein the spindle unrotatably supports the inner ring of the middle bearing, the pair of ratchet gears, and the pair of damping thrust bearings, wherein the moving bracket is unrotatably mounted on the outer ring of the middle bearing, and wherein the fixed bracket is unrotatably mounted on the pair of damping thrust bearings.

13. A display apparatus comprising:
a display monitor;
a moving bracket to support the display monitor;
a fixed bracket pivotably connected to the moving bracket;
a display tilting apparatus to rotatably support the display monitor, wherein the display tilting apparatus comprises:
a spindle;
a middle bearing mounted on the spindle and coupled to the moving bracket;
a pair of damping thrust bearings mounted on the spindle and coupled to the fixed bracket; and
a ratchet-pawl assembly mounted on the spindle and connected to the moving bracket, wherein the ratchet-pawl assembly is in a lock position and the pair of damping thrust bearings are to provide a first frictional force during rotation of the moving bracket in a first direction, and wherein the ratchet-pawl assembly is in an unlock position and the middle bearing is to provide a second frictional force during rotation of the moving bracket in a second direction.

14. The display apparatus of claim 13, wherein the spindle, the middle bearing, the ratchet-pawl assembly, and the pair of damping thrust bearings are to rotate along with the moving bracket in the first direction such that the pair of damping thrust bearings are to provide the first frictional force when the ratchet-pawl assembly is in the lock position.

15. The display apparatus of claim 13, wherein the middle bearing is to rotate along with the moving bracket in the second direction such that the middle bearing is to provide the second frictional force when the ratchet-pawl assembly is in the unlock position.
